(19) United States
(12) Patent Application Publication
(10) Pub. No.: US 2025/0214207 A1
(43) Pub. Date: Jul. 3, 2025

(54) WRENCH

(71) Applicant: Shenzhen Kaisennick Intelligent Technology Co., Ltd., Shenzhen (CN)

(72) Inventor: YONGKAI ZHOU, Shenzhen (CN)

(21) Appl. No.: 18/398,279

(22) Filed: Dec. 28, 2023

(51) Int. Cl. B25B 13/48; G01R 19/145

(52) U.S. Cl. CPC B25B 13/48; G01R 19/145

(57) ABSTRACT

The present application provides a wrench including a plate A and a plate B, an outer edge of the plate A is provided with a clamp block, a side of the plate B is hinged with a side of the plate A to enable them to be folded with each other, an outer edge of the plate A is provided with a clamp groove that cooperates with the clamp block to fix the plate A and the plate B. Additionally, the plate A and plate B are respectively provided with a screw hole A and a screw hole B that correspond to electrode posts. The present application utilizes a hinge design, rendering the wrench is easy to change its shape, reducing a probability of being affected by another electrode post during a twisting process of the wrench and improving a smooth loading and unloading electrode post screws.

### TECHNICAL FIELD

The present application relates to the field of screwing tool technologies, and in particular, to a wrench.

### BACKGROUND

When disassembling and assembling screws on an outer ring of an electrode post on a stop barking device, and when detecting whether there is electricity on the electrode post, a wrench is usually used.

The wrench that is compatible with the electrode post of the stop barking device b in an existing technology is usually shown in FIG. 1, which is an integrated whole plate (plate C a). Multiple screw holes are respectively provided on the plate C a to adapt to the electrode post. In a middle of the plate C a, there is also a power-on testing mechanism that extends through a wire into the screw hole. When the screw hole is stuck on an outer wall of the electrode post screw of the stop braking device, if the electrode post is electrified, the power-on testing mechanism will emit light, a rotary wrench can be used to load and unload screws. In summary, the existing wrench can not only disassemble and disassemble electrode post screws, but also determine an electrification status of the electrode post.

However, during a process of implementing the technical solution in the embodiments of the present application, inventors of the present application have found at least the following technical problems in the above-mentioned technology:

Due to a fact that there are usually two electrode posts located relatively close to each other on the stop braking device, the screw hole on plate C a in FIG. 1 is stuck on the outer wall of one of the electrode posts. When the screw is rotated, a rotation angle is usually limited or obstructed by the other electrode post. When the screw contacts the other electrode post, it must be removed and changed direction for rotation until the screw is removed or installed, rendering the rotation process of the wrench more time-consuming; at the same time, the wrench in FIG. 1 has a large volume and is inconvenient to carry.

### SUMMARY

In order to overcome the shortcomings of time-consuming and inconvenient volume reduction in wrench rotation in related technologies, an embodiment of the present application provides a wrench that reduces the volume of the wrench while reducing a hindrance during a rotation process.

The technical solution adopted to solve the technical problem in the embodiment of the present application is:
a wrench, including a plate A and a plate B,
a clamp block is provided on an outer edge of the plate A;
a design that a side of the plate A is hinged with a side of the plate B to enable to be folded with each other, an outer edge of the plate B is provided with a clamp groove that cooperates with the clamp block to fix the plate A and the plate B, where the plate A and plate B are respectively provided with a screw hole A and a screw B that correspond to electrode posts.

In an embodiment of the present disclosure, an outer edge of the plate A is provide with a concave cavity, the clamp block is provided in the concave cavity.

In an embodiment of the present disclosure, a dimeter of the screw hole A is different from a dimeter of the screw hole B.

In an embodiment of the present disclosure, the plate A is provided with an installation chamber A, a power-on testing mechanism is provided in the installation chamber A;
where, the power-on testing mechanism includes a circuit board provided in the installation chamber A, the circuit board is electrically connected to a lamp body, the plate B and the plate A are further respectively provided with an installation chamber B communication with the screw hole A and the screw hole B, each installation chamber B is provided with a wire connected to the circuit board and the electrode post; when the screw hole A or the screw hole B contacts the electrode post, the lamp body emits light.

In an embodiment of the present disclosure, the installation chamber B on the plate A is configured to connect to the installation chamber A, the plate A is provided with a notch that communicates with the installation chamber A, a corresponding wire extends into a corresponding installation chamber B through the notch.

In an embodiment of the present disclosure, the plate A is further provided with a transparent cover covering the installation chamber A, an outer surface of the transparent cover is flush with an outer surface of the plate B.

The advantages of the embodiment of the present application are:
1. The present application utilizes a hinge design of the plate A and plate B, rendering it easy for the wrench to change shape during a twisting process, reducing a probability of being affected by another electrode post during the twisting process, and improving a smooth loading and unloading of electrode post screws with the wrench, making loading and unloading relatively time-saving;
2. Furthermore, the clamp block and the clamp groove are designed on the outer edges of the plate A and the plate B, respectively. Coupled with the hinged design of the plate A and the plate B, it can be quickly folded and fixed, stably reducing a volume of the wrench when carried out, and relatively improving a convenience of carrying.

### BRIEF DESCRIPTION OF DRAWINGS

FIG. 1 is a schematic diagram of a structure of a wrench of an existing technology.

FIG. 2 is a schematic diagram of a structure of a wrench provided in an embodiment of the present application.

FIG. 3 is a schematic diagram of the structure in FIG. 2 provided by an embodiment of the present application after removing a transparent cover.

FIG. 4 is a schematic diagram of the structure of the wrench in a second embodiment provided by the present application.

FIG. 5 is a schematic diagram of the structure of the wrench provided in the second embodiment of the present application.

Reference number: 1—Plate A; 11—Clamp block; 12—Screw hole A; 13—Concave cavity; 14—Installation chamber A; 15—Power-on testing institution; 151—Circuit board; 152—Lamp body; 153—Wire; 16—Transparent cover; 2—Plate B; 21—Clamp groove; 22—Screw hole B; a—Plate C; b—Stop barking device.

### DESCRIPTION OF EMBODIMENTS

The technical solution in the implementation of the present application is to solve the shortcomings of time-consuming and inconvenient of reduction of a volume of a wrench in related technologies. The overall idea is as follows.

### Embodiment 1

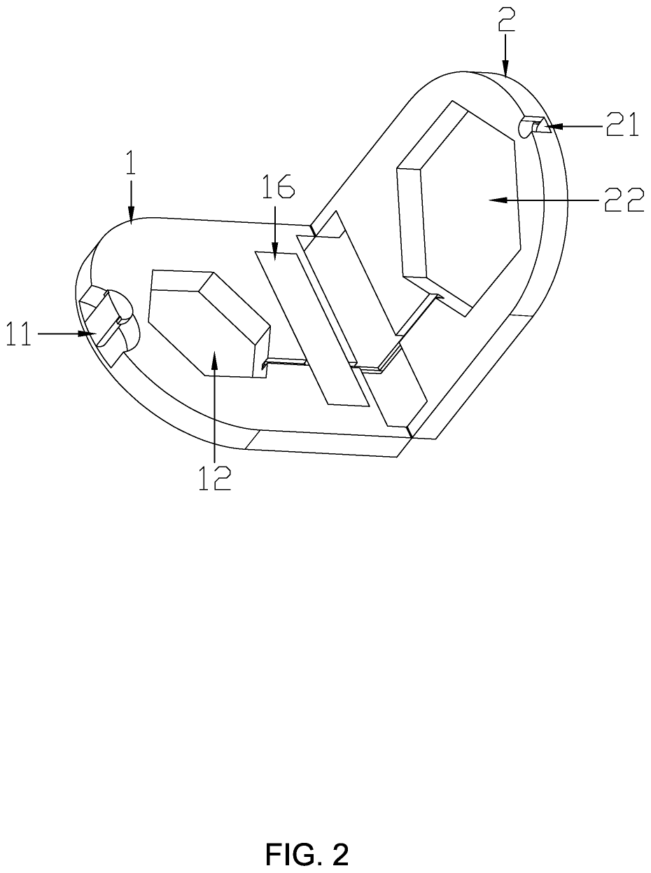

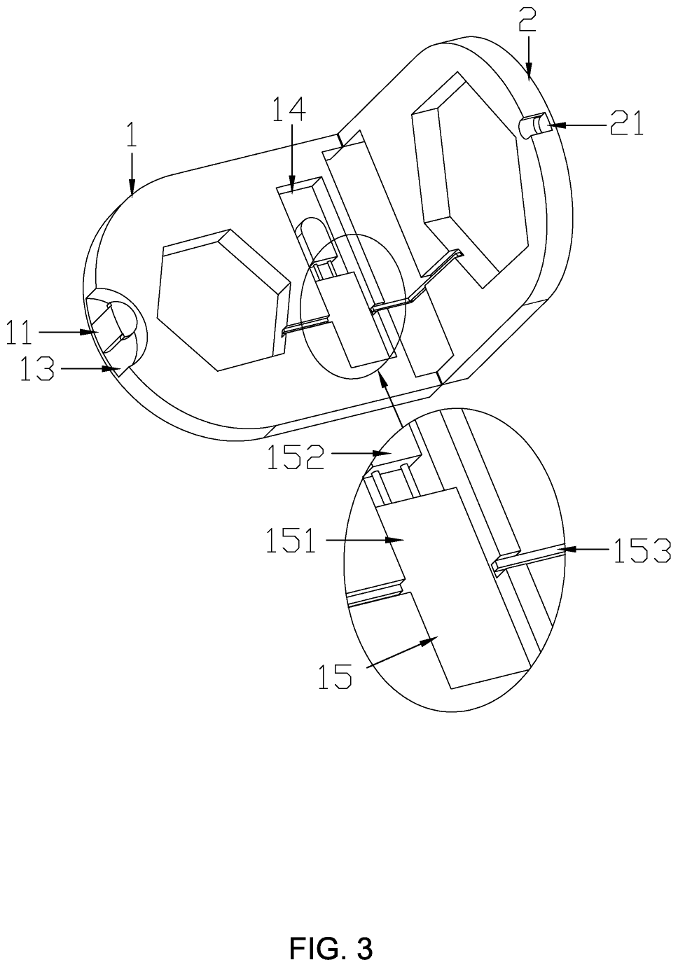

Please refer to FIGS. 2 to 3, a wrench including a plate A1 and a plate B2.

An outer edge of the plate A1 is provided with a clamp block 11.

A side of the plate B2 is hinged with a side of the plate A1, allowing them to be folded. A clamp groove 21 is provided on an outer edge of the plate B 2 that cooperates with the clamp block 11 to fix the plate A1 and the plate B2, the plate A 1 and the plate B 2 are respectively provided with a screw hole A12 and a screw hole B 22 that correspond to electrode posts.

In this embodiment, a combination of the plate A1 and plate B 2 through a hinge design so that it easy for the wrench to change its shape during a twisting process, reducing a probability of being affected by another electrode post during the twisting process, improving a smooth loading and unloading of electrode post screws by the wrench, and rendering loading and unloading relatively time-saving.

In an implementation mode, a clamp block 11 and a clamp groove 21 are designed on an outer edge of the plate A1 and the plate B2, respectively. Coupled with the hinged design of the plate A1 and the plate B2, it can be quickly folded and fixed, stably reducing a volume of the wrench when carried out, and relatively improving a convenience of carrying.

There is a concave cavity 13 on an outer edge of the plate A1, and the clamp block 11 is provided in the concave cavity 13. As shown in FIGS. 2 and 3, it can be seen that designing the clamp block 11 in the concave cavity 13, relative to the design on the outside edge of plate A1, it is undoubtedly to reduce an overall space occupation area of the wrench.

A diameter of the screw hole A12 is different from a dimeter of the screw hole B22. This design is to enable the wrench to load and unload screws on electrode posts of various specifications, improving an adaptability of the wrench.

The plate A1 is provided with an installation chamber A14, and a power-on testing mechanism 15 is provided in the installation chamber A14.

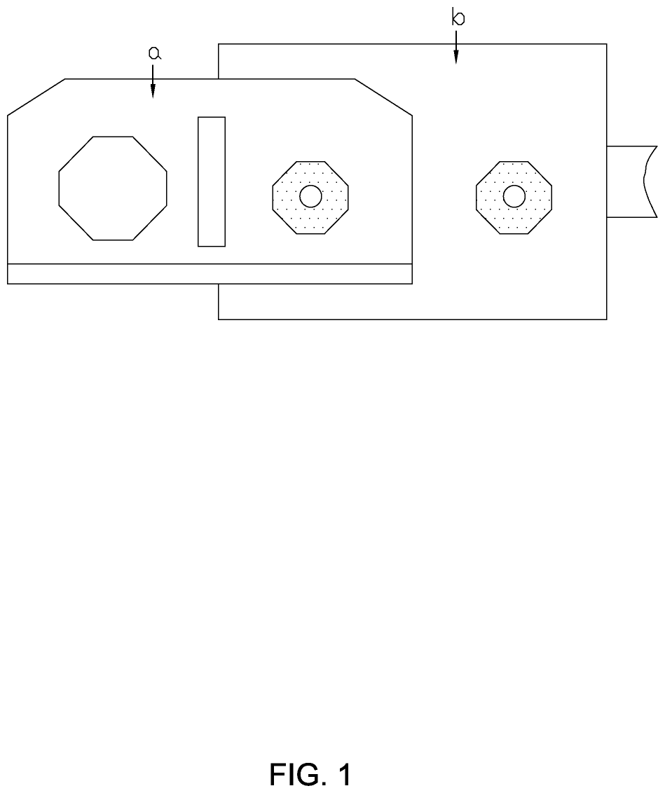

The power-on testing mechanism 15 includes a circuit board 151 provided in the installation chamber A14, the circuit board 15 is electrically connected to a lamp body 152. The plate B 2 and the plate A 1 are also respectively provided with an installation chamber B communication with the screw hole A 12 and the screw hole B 22, and each installation chamber B is provided with a wire 153 connected to the circuit board 151 and the electrode post; when the screw hole A 12 or screw hole B 22 contacts the electrode post, the lamp body 152 emits light. Specifically, if the electrode post of a stop braking device b is electrified, the wire 153 in the installation chamber B conducts electricity to the electrode post and conducts it to the circuit board 151. Through the circuit board 151, the lamp body 152 can be controlled to be electrified and emit light. A control principle and device specification are the same as those of the power-on testing mechanism 15 in FIG. 1, which is a prior art and will not be repeated here.

The installation chamber B on the plate A 1 is designed to be connected to the installation chamber A 14, and the plate A 1 is provided with a notch that communicates with the installation chamber A 14. A corresponding wire 153 extends into a corresponding installation chamber B through the notch. A design of the notch allows the wire 153 to smoothly extend into the installation chamber B, and it should be noted that the wire 153 can be fixed in the notch and installation chamber B by bonding, reducing an impact on a folding during folding the wrench.

The plate A 1 is further provided with a transparent cover 16 covering the installation chamber A 14, an outer surface of the transparent cover 16 is flush with an outer surface of plate B 2. A design of the transparent cover 16 can provide protection for the power-on testing mechanism 15, reducing its probability of collision damage.

It should be noted that the transparent cover 16 can also be fixed to the plate A 1 by bonding.

The wrench provided in the present application can be used in two states.

When in use, the screw hole A12 or the screw hole B22 is clamped outside a screw of an adapted electrode post. When the two come into contact, if there is electricity in the electrode post, the lamp body 152 connected to the circuit board 151 will light up, otherwise it will not light up; a position of holding, which can be installed or removed by rotating the screws with the plate A 1 or the plate B 2 in a clamped state. The present application will use two foldable and movable plate A 1 or plate B 2 to be unaffected by other electrode post during a rotation process of the wrench.

In a carrying state, the plate A 1 or the plate B 2 is pressed, and the clamp block 11 is pressed into the clamp groove 21 to achieve the folding and storage of the wrench, thereby improving the convenience of carrying the wrench.

In another embodiment, the power-on testing mechanism 15 can perform electrical shock function testing on a device with electrical shock function. A transmitter and a receiver of the device with electrical shock function are turned on, and two metal parts in the power-on testing mechanism 15 are clamped on the electrical shock column of the receiver. Then, an electrical shock button of the transmitter is pressed, and the lamp body 152 of a testing tool will light up after the receiver receives it. The lamp body 152 is a neon bubble lamp, which can adjust an electric shock intensity by judging a brightness of the lamp and verify whether the electric shock function of the receiver is normal.

The screw hole is hexagonal and can be used as a wrench. The receiver is provided with a pair of electric shock columns, long and short. When disassembling the electric shock column, this wrench can be used for disassembly.

### Embodiment 2

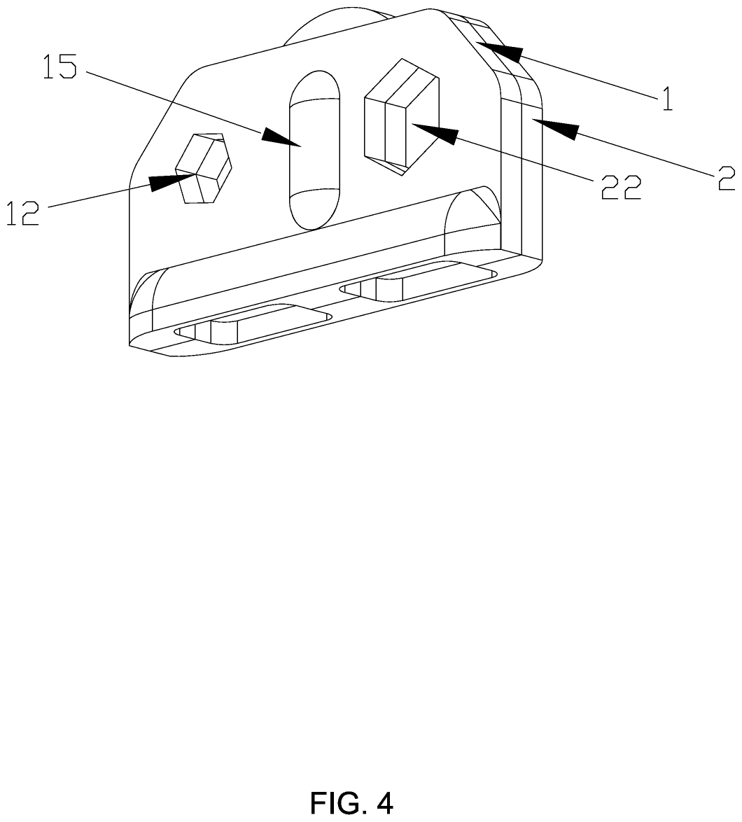

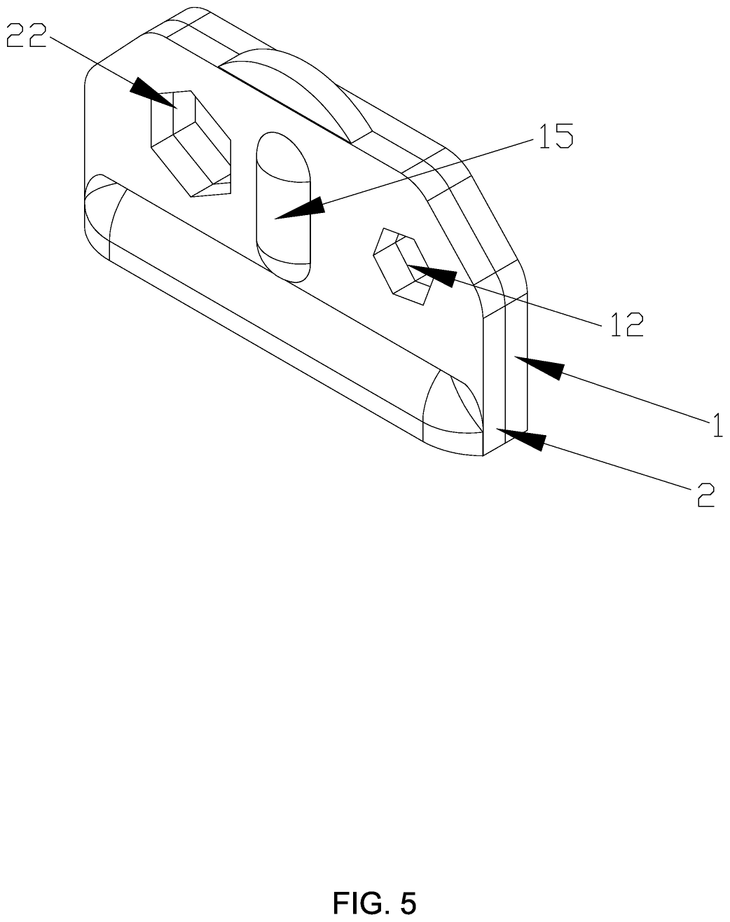

Please refer to FIGS. 4 to 5. The distinguishing feature between Embodiment 2 and Embodiment 1 is that the plate A 1 and the plate B 2 are fixedly connected, and the power-on testing mechanism 15 is provided in the plate A 1 and plate B 2. The plate A 1 and plate B 2 are symmetrically provided with screw holes A 12 and B 22 with different diameters.

The advantage of this setting is that the fixed connection of the plate A 1 and plate B 2 not only meets the requirements for loading and unloading electrode post screws, but also improves strength and avoids damage to a hinge joint, which affects use. At the same time, the power-on testing mechanism 15 is build-in, which can provide safer testing.

Finally, it should be noted that the above embodiments are merely illustrative examples provided in the present application, rather than limiting the implementation modes. For ordinary technical personnel in their respective fields, different forms of changes or variations can be made based on the above explanation. It is not necessary and impossible to exhaustively list all implementation modes here. The obvious changes or variations arising from this are still within the protection scope of the present application.

What is claimed is:

1. A wrench, comprising:
a plate A (1), wherein an outer edge of the plate A (1) is provided with a clamp block (11);
a plate B (2), configured to hinge with one side of the plate A (1) so that the plate A (1) and the plate B (2) can be folded to each other, an outer edge of the plate B (2) is provided with a clamp groove (21) that cooperates with the clamp block (11) to fix the plate A (1) and the plate B (2), wherein the plate A (1) and the plate B (2) are respectively provided with a screw hole A (12) and a screw hole B (22) that correspond to electrode posts.

2. The wrench according to claim 1, wherein an outer edge of the plate A (1) is provided with a concave cavity (13), and the clamp block (11) is provided in the concave cavity (13).

3. The wrench according to claim 1, wherein a dimeter of the screw hole A (12) is different from that of the screw hole B (22).

4. The wrench according to claim 1, wherein the plate A (1) is provided with an installation chamber A (14), a power-on testing mechanism (15) is provided in the installation chamber A (14);
wherein, the power-on testing mechanism (15) comprises a circuit board (151) provided in the installation chamber A (14); the circuit board (151) is electrically connected to a lamp body (152); the plate B (2) and the plate A (1) are respectively provided with an installation camber B communication with the screw hole A (12) and the screw B (22); each installation chamber B is provided with a wire (153) connected to the circuit board (151) and the electrode post; when the screw hole A (12) or screw hole B (22) contacts the electrode post, the lamp body (152) emits light.

5. The wrench according to claim 4, wherein the installation chamber B on the plate A (1) is configured to connect to the installation chamber A (14); the plate A (1) is provided with a notch that communicates with the installation chamber A (14), a corresponding wire (153) extends into a corresponding installation chamber B through the notch.

6. The wrench according to claim 4, wherein the plate A (1) is further provided with a transparent cover (16) covering the installation chamber A (14), an outer surface of the transparent cover (16) is flush with an outer surface of the plate B (2).
